(19) United States
(12) Patent Application Publication
(10) Pub. No.: US 2023/0402253 A1
(43) Pub. Date: Dec. 14, 2023

(54) MULTI CHARGED PARTICLE BEAM EVALUATION METHOD, MULTI CHARGED PARTICLE BEAM WRITING METHOD, INSPECTION METHOD FOR APERTURE ARRAY SUBSTRATE FOR MULTI CHARGED PARTICLE BEAM IRRADIATION APPARATUS, AND COMPUTER-READABLE RECORDING MEDIUM

(71) Applicant: NuFlare Technology, Inc., Yokohama-shi (JP)

(72) Inventors: Hirofumi MORITA, Setagaya-ku (JP); Yoshikuni GOSHIMA, Yokohama-shi (JP)

(73) Assignee: NuFlare Technology, Inc., Yokohama-shi (JP)

(21) Appl. No.: 18/328,026

(22) Filed: Jun. 2, 2023

(30) Foreign Application Priority Data
Jun. 10, 2022 (JP) 2022-094497

(51) Int. Cl. H01J 37/317; H01J 37/04

(52) U.S. Cl. CPC H01J 37/3177; H01J 37/045; H01J 2237/0437; H01J 2237/0453; H01J 2237/24592; H01J 2237/24578; H01J 2237/24528

(57) ABSTRACT

In one embodiment, a multi charged particle beam evaluation method is for evaluating trajectories of a plurality of individual beams in a multi charged particle beam which has passed through a plurality of openings provided in an aperture array substrate. The method includes measuring positions of the plurality of individual beams at each of a plurality of heights, in an optical axis direction, of an imaging plane of the multi charged particle beam, or a measurement plane on which a mark for beam position measurement is formed, the plurality of heights being different from each other, and extracting a singular beam in which a beam trajectory has changed among the plurality of individual beams based on a position difference, the position difference being a difference between beam positions of the plurality of individual beams measured at each of the plurality of heights.

### CROSS REFERENCE TO RELATED APPLICATION

This application is based upon and claims benefit of priority from the Japanese Patent Application No. 2022-94497, filed on Jun. 10, 2022, the entire contents of which are incorporated herein by reference.

### FIELD

The present invention relates to a multi charged particle beam evaluation method, a multi charged particle beam writing method, an inspection method for aperture array substrate for a multi charged particle beam irradiation apparatus, and a computer-readable recording medium.

### BACKGROUND

As LSI circuits are increasing in density, the line width of circuits of semiconductor devices is becoming finer. To form a desired circuit pattern onto a semiconductor device, a method of reducing and transferring, by using a reduction-projection exposure apparatus, onto a wafer a highly precise original image pattern formed on a quartz is employed. The highly precise original image pattern is written by using an electron beam writing apparatus, in which a technology commonly known as electron beam lithography is used.

For example, a writing apparatus using a multi-beam is known. A large number of beams can be radiated at one time using a multi-beam, as compared to when a single beam is used for writing, thus the throughput can be significantly improved. In a multi-beam writing apparatus, a multi-beam is formed, for example, by passing an electron beam emitted from an electron source through a shaping aperture array (SAA) substrate having a plurality of openings, and beams are independently blanking-controlled by a blanking aperture array (BAA) substrate, and those beams which are not shielded are reduced by an optical system, deflected by a deflector, and irradiated to a desired position on a sample.

In a multi-beam writing apparatus, dust and/or contamination (dirt produced by beam irradiation) adhering to an SAA substrate may be charged to cause deflection which is not expected according to an electron optical design, thus the trajectories of the beams in part of a multi-beam may be bent to an angle different from the designed angle. Hereinafter, such a change in angle of a beam trajectory in the vicinity of an SAA substrate is called an SAA angle deviation.

The SAA substrate and the BAA substrate are closely disposed, thus the SAA angle deviation may be caused by electrical charging of dust and/or contamination adhering to the BAA substrate, or electrical charging of an insulator exposed and/or foreign materials adhered due to instability of the manufacturing process. The aperture array substrate, such as an SAA substrate and a BAA substrate, used in a multi-beam writing apparatus has a great number of microscopic openings, for example, 512 rows×512 columns, totally 260000 or more, and a complicated electrode structure, thus it is difficult to detect all of adhesion and exposure of these dust and insulator by an inspection such as observation and analysis in advance. An inspection technique for large-scale (a great number of) microstructures has been highly developed along with the development of LSI technology. However, in the inspection of the aperture array substrate, when the electron beam is cut off or allowed to pass through nearby, whether the beam trajectory is affected gives the final pass/fail criteria, thus the inspection cannot be handled by an inspection technique for an electronic circuit, and cannot be sufficiently addressed by the conventional inspection technique for LSI.

There is a problem in that the SAA angle deviation worsens the distortion and aberration of a multi-beam on the writing surface (sample surface), and the accuracy of writing is reduced. In the past, the SAA angle deviation could not be measured for each individual beam, which prevents improvement of the accuracy of writing. In addition, there is a problem in that a cause of an SAA angle deviation, that is, a local defect (such as adhesion of dust, a structure or a material to which contamination is likely to adhere, exposure of an insulator, and adhesion of foreign materials) of an SAA substrate and a BAA substrate cannot be completely detected.

### BRIEF DESCRIPTION OF THE DRAWINGS

FIG. 1 is a schematic configuration diagram of a writing apparatus according to an embodiment of the present invention.

FIG. 2 is a plan view of a shaping aperture array substrate.

FIG. 3 is a flow chart for explaining a multi charged particle beam evaluation method according to the embodiment.

FIG. 4A, FIG. 4B are views illustrating examples of height change when a positional deviation amount of an individual beam is measured.

FIG. 5 is a view illustrating an example of a beam position difference.

### DETAILED DESCRIPTION

In one embodiment, a multi charged particle beam evaluation method is for evaluating trajectories of a plurality of individual beams in a multi charged particle beam which has passed through a plurality of openings provided in an aperture array substrate. The method includes measuring positions of the plurality of individual beams at each of a plurality of heights, in an optical axis direction, of an imaging plane of the multi charged particle beam, or a measurement plane on which a mark for beam position measurement is formed, the plurality of heights being different from each other, and extracting a singular beam in which a beam trajectory has changed among the plurality of individual beams based on a position difference, the position difference being a difference between beam positions of the plurality of individual beams measured at each of the plurality of heights.

An embodiment of the present invention will be described below with reference to the drawings. In the embodiment, a configuration using an electron beam as an example of a charged particle beam will be described. The charged particle beam is not limited to the electron beam. For example, the charged particle beam may be an ion beam. In the embodiment, a multi beam writing apparatus using multi electron beams will be described as an example of a multi charged particle beam irradiation apparatus. The multi charged particle beam irradiation apparatus is not limited to the multi beam writing apparatus, and the embodiment can also be applied to the multi beam inspection apparatus.

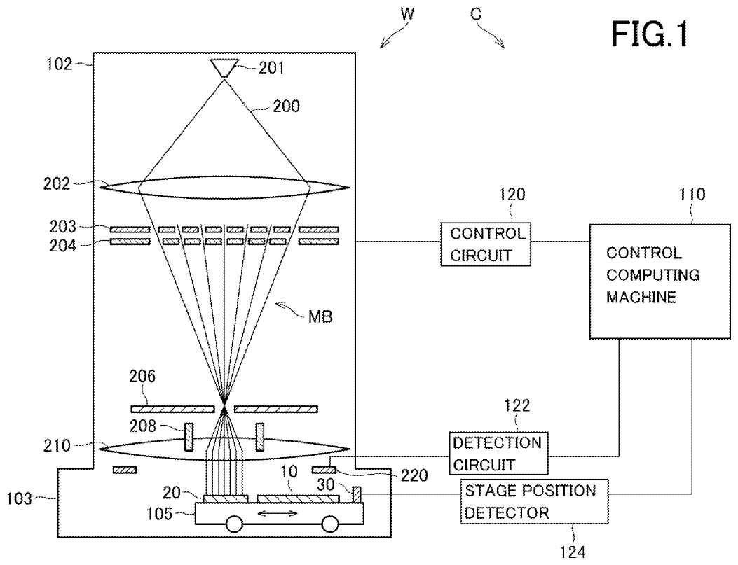

FIG. 1 is a schematic configuration diagram of a multi-beam writing apparatus according to an embodiment of the present invention. As illustrated in FIG. 1, the multi-beam writing apparatus includes a writer W and a controller C. The writer W includes an electron optical column 102, and a writing chamber 103. In the electron optical column 102, an electron source 201, an illumination lens 202, a shaping aperture array substrate 203, a blanking aperture array substrate 204, a limiting aperture substrate 206, a deflector 208 and an objective lens 210 are disposed, which constitute the electron optical system of the multi-beam writing apparatus.

In the writing chamber 103, an XY stage 105 movable in the XY direction, and a detector 220 are disposed. The XY stage 105 may be movable in the Z direction. A substrate 10 as a writing target is disposed on the XY stage 105. The substrate 10 includes an exposure mask for semiconductor device fabrication, and a semiconductor substrate (silicon wafer) on which a semiconductor device is fabricated. In addition, the substrate 10 includes mask blank which is coated with resist and on which nothing has been written.

Furthermore, a mark 20 for beam position measurement is disposed on the XY stage 105. The mark 20 is a metal mark in a cross shape, for example. The detector 220 detects reflected electrons (or secondary electrons) when the mark 20 is scanned by the beam.

In addition, a mirror 30 for stage position measurement is disposed on the XY stage 105.

The controller C has a control computing machine 110, a control circuit 120, a detection circuit 122 and a stage position detector 124. The stage position detector 124 radiates a laser, receives light reflected from the mirror 30, and detects the position of the XY stage 105 based on the principle of the laser interference method.

In FIG. 1, the components necessary to explain the embodiment are illustrated, and other components are not illustrated.

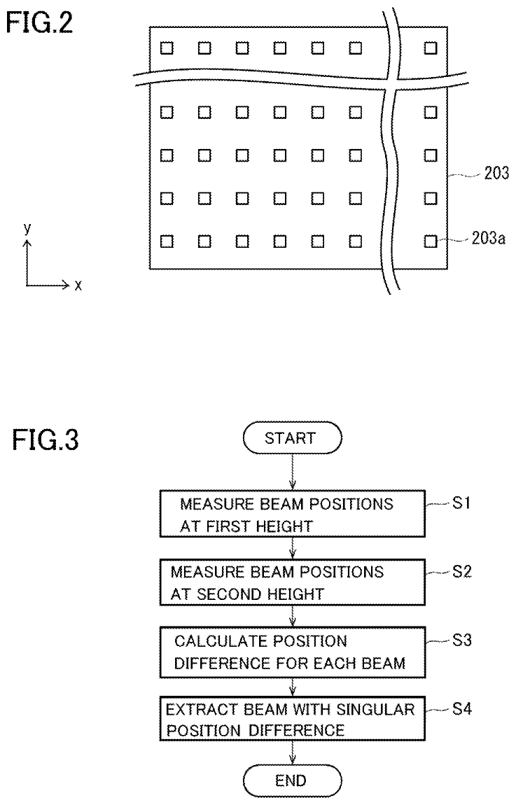

FIG. 2 is a conceptual diagram illustrating the configuration of the shaping aperture array (SAA) substrate 203. In FIG. 2, in the shaping aperture array substrate 203, openings (first openings) 203a in vertical (y direction) p rows×horizontal (x direction) q columns (p, q>=2) are formed in a matrix with a predetermined arrangement pitch. For example, the openings 203a in 512 rows×512 columns are formed. The openings 203a are formed as rectangles in the same dimensional shape. The openings 203a may be circular. The beams in part of the electron beams 200 respectively pass through the plurality of openings 203a, thereby forming a multi-beam MB.

The blanking aperture array substrate 204 is provided below the shaping aperture array substrate 203, and passage holes (second openings) are formed corresponding to the arrangement positions of the openings 203a of the shaping aperture array substrate 203. In each passage hole, a blanker consisting of a set of two electrodes forming a pair is disposed. One electrode of the blanker is fixed to the ground potential, and the other electrode is switched between the ground potential and another potential. An electron beam passing through a passage hole is independently deflected by a voltage applied to a corresponding blanker. In this manner, a plurality of blankers perform blanking deflection on corresponding beams in the multi-beam MB which has passed through the plurality of openings 203a of the shaping aperture array substrate 203.

The electron beams 200 emitted from the electron source 201 (emitter) are bent (refracted) by the illumination lens 202 to illuminate the entire shaping aperture array substrate 203. The electron beams 200 illuminate an area including the plurality of (all) openings 203a. Part of the electron beams 200 pass through a plurality of openings 203a of the shaping aperture array substrate 203, thereby forming a plurality of electron beams (multi-beam MB). The multi-beam MB passes through corresponding blankers of the blanking aperture array substrate 204. The blankers perform blanking control on respective passing beams so that each beam is in an ON state for a set exposure time (irradiation time).

Due to the refraction of the illumination lens 202, the multi-beam MB which has passed through the blanking aperture array substrate 204 travels to an opening (a third opening) formed in the center of the limiting aperture substrate 206. The multi-beam MB then forms crossover CO at the height position of the opening of the limiting aperture substrate 206.

A beam deflected by a blanker of the blanking aperture array substrate 204 is displaced in position from the opening of the limiting aperture substrate 206, and is shielded by the limiting aperture substrate 206. In contrast, a beam not deflected by a blanker of the blanking aperture array substrate 204 passes through the opening of the limiting aperture substrate 206. In this manner, the limiting aperture substrate 206 shields the beam which is deflected by a blanker to achieve a beam OFF state.

The beam for one shot is formed by the beam which has passed through the limiting aperture substrate 206 during a time from beam ON to beam OFF. Each of the beams in the multi-beam MB which has passed through the limiting aperture substrate 206 becomes an aperture image with a desired reduction ratio of the opening 203a of the shaping aperture array substrate 203 by the objective lens 210, and the focus of the beam is adjusted on the substrate 10. The beams (the entire multi-beam) which have passed through the limiting aperture substrate 206 are collectively deflected in the same direction by the deflector 208, and irradiated to respective irradiation positions of the beams on the substrate 10.

For example, when the XY stage 105 is continuously moved, the irradiation position of each beam is controlled by the deflector 208 so as to follow the movement of the XY stage 105. The beams in the multi-beam MB radiated at one time are ideally arranged with the pitch which is the product of the arrangement pitch of the plurality of openings 203a of the shaping aperture array substrate 203 and the above-mentioned desired reduction ratio. The writing apparatus performs a writing operation by a raster scan method for irradiating with successive shot beams continuously, and when a desired pattern is written, an unnecessary beam is controlled at a beam-off by the blanking control.

In such a writing apparatus, dust and/or contamination adhering to the shaping aperture array substrate 203 may be charged to cause deflection which is not expected in an electron optical design, and in the beams in part of the multi-beam, an “SAA angle deviation” may occur, in which the beam trajectories are bent to an angle different from the designed angle in the vicinity of the shaping aperture array (SAA) substrate 203. The SAA angle deviation may be caused by electrical charging of dust and/or contamination adhering to the blanking aperture array substrate 204, or electrical charging of an insulator exposed and/or foreign materials adhered due to instability of the manufacturing process.

In order to improve the accuracy of pattern writing on the substrate 10, it is necessary to identify the beam in which an SAA angle deviation has occurred. A multi-beam evaluation method for identifying the beam in which an SAA angle deviation has occurred will be described with reference to the flowchart illustrated in FIG. 3.

First, the positions of a plurality of individual beams among a large number of individual beams included in a multi-beam are measured at two different heights (a first height z₁, a second height z₂) in the vicinity of a writing surface (steps S1, S2). Here, the positions of beams are beam incident positions on a measurement plane perpendicular to an optical axis, and normally, are each represented by a pair of an x coordinate value and a y coordinate value. For example, only the individual beams to be measured are turned on one by one sequentially, each beam is deflected by the deflector 208 to scan the mark 20, and electrons reflected by the mark 20 are detected by the detector 220. The detection circuit 122 informs the control computing machine 110 of the amount of electrons detected by the detector 220. The control computing machine 110 obtains a scan waveform from the detected amount of electrons, and calculates the position of each individual beam relative to the position of the XY stage 105.

The individual beam to be on is sequentially switched to determine the position of each beam. The number of individual beams for which the positions are determined is not particularly limited, and for example, 7×7 beams are selected as a measurement target at regular intervals from 512×512 beams included in a multi-beam.

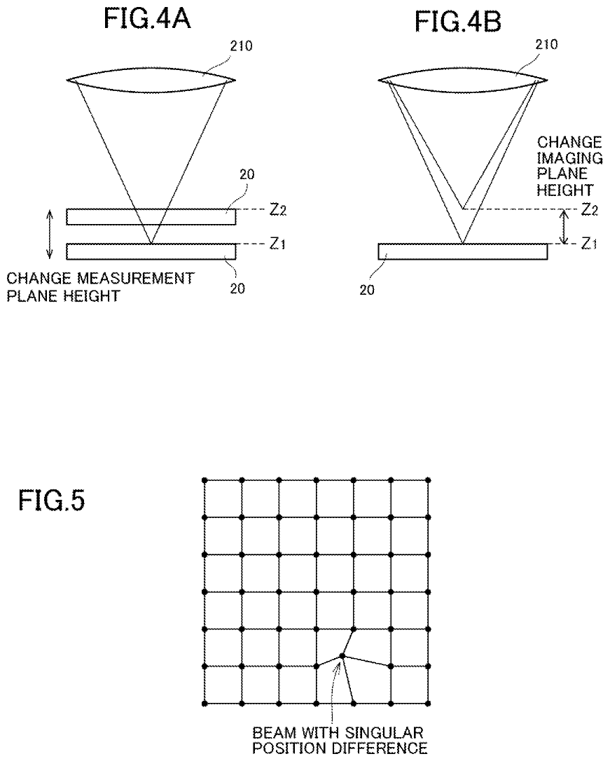

Note that “different heights” or “height is changed” may refer to “changing the measurement plane height and fixing the imaging plane height” as illustrated in FIG. 4A, in which the XY stage 105 is moved in the Z direction (optical axis direction, or beam travel direction) so that the height of the surface (measurement plane) of the mark 20 in the optical axis direction is changed, and the height of an imaging plane of a multi-beam is fixed, or may refer to “fixing the measurement plane height and changing the imaging plane height” as illustrated in FIG. 4B, in which the height of an imaging plane of a multi-beam in the optical axis direction is changed with the height of the measurement plane fixed. When the objective lens 210 included in the electron optical system of the writing apparatus is a magnetic lens, the height of an imaging plane of a multi-beam can be changed by changing the excitation of the objective lens 210 using the control circuit 120. When the objective lens 210 is an electrostatic lens, an applied voltage should be changed. For example, instead of the objective lens, an applied voltage of an electrostatic focus correction lens (not illustrated) disposed between the deflector 208 and the mark 20 may be changed.

In this manner, the height of an imaging plane of a multi-beam can be changed by changing the amount of excitation (excitation in a magnetic lens, an applied voltage in an electrostatic lens) of the lens (such as an objective lens, a focus correction lens) disposed between the shaping aperture array substrate 203 and the mark 20 in the optical axis direction. Note that the height of an imaging plane may be changed by changing the amount of excitation of a plurality of lenses with a constant ratio.

The difference between the two heights z₁ and z₂ is preferably several μm to several tens μm. The origin of the height coordinate z may be determined in any manner as long as the origin is fixed during execution of the method of the present application. Note that the beam does not need to be completely focused on the surface (the measurement plane) of the mark 20 at the heights z₁, z₂. For example, focus may be completely made at one height and defocus may occur at the other height, or defocus may occur at both heights.

For each beam, the difference (position difference) between the position at the first height z₁ and the position at the second height z₂ is calculated (step S3). The calculation of the position difference is performed for each of the x coordinate value and the y coordinate value.

The position difference of each beam is plotted as a displacement from a normal position, and beams with a singular position difference are extracted (step S4). The singular position difference refers to a situation in which, for example, the absolute value and/or the direction of the position difference deviate substantially from those of surrounding beams (by a predetermined value or greater). For example, a beam at a position where position difference is large, beams at a position where the change in position difference is large and its vicinity, and beams at a position where the direction of position difference is changed and in its vicinity are extracted as singular beams. FIG. 5 illustrates an example of a beam with a singular position difference. A beam with a singular position difference may be extracted by the control computing machine 110, or an operator checking visually.

A beam in which an SAA angle deviation has occurred has such a beam trajectory in the objective lens 210 that deviates from surrounding beams in which an SAA angle deviation has not occurred.

When the excitation of the objective lens 210 is changed by the above-mentioned “fixing the measurement plane height and changing the imaging plane height”, a convergence force to each beam in the objective lens 210 is changed, and the beam position on the measurement plane is moved. In a beam in which an SAA angle deviation has not occurred, the movement of the beam position has a continuous and gradual change; however, a beam in which an SAA angle deviation has occurred passes along a trajectory which deviates from surrounding beams in which an SAA angle deviation has not occurred, thus the movement of the beam position exhibits a different tendency. Therefore, the beams in which an SAA angle deviation has occurred can be identified by extracting those beams positions of which change singularly in response to change in the excitation of the objective lens.

In the vicinity of an imaging plane, beams substantially go straight, thus when the height of the surface for beam position measurement is changed by the above-mentioned “changing the measurement plane height and fixing the imaging plane height”, the beam position moves within the measurement plane. In a beam in which an SAA angle deviation has not occurred, the movement of the beam position has a continuous and gradual change; however, a beam in which an SAA angle deviation has occurred is incident from a position away from surrounding beams in which an SAA angle deviation has not occurred, thus the incidence angle to the imaging plane is significantly changed, and as a result, the movement of the beam position exhibits a different tendency. Therefore, the beams in which the incidence angle to the imaging plane has significantly changed, in other words, the beams in which an SAA angle deviation has occurred can be identified by extracting those beams positions of which change specifically in response to change in the beam position measurement plane height.

Beams in which an SAA angle deviation has occurred identified by the above method are excluded, and a pattern is written on the substrate 10 using the writing apparatus. First, the control computing machine 110 reads writing data from a storage device (not illustrated), and performs a multi-stage data conversion process on the writing data to generate shot data specific to the apparatus. The shot data defines the irradiation amount and irradiation position coordinates of each shot.

The control computing machine 110 outputs the irradiation amount of each shot to the control circuit 120 based on the shot data. The control circuit 120 determines an irradiation time t by dividing the input irradiation amount by a current density. When making a corresponding shot, the control circuit 120 controls the deflection voltage to be applied to a corresponding blanker so as to achieve beam ON for the irradiation time t. Each beam in which an SAA angle deviation has occurred is set to beam OFF.

The control computing machine 110 outputs deflection position data to the control circuit 120 so that the beams are deflected to the positions (coordinates) indicated by the shot data. The control circuit 120 calculates the amount of deflection, and applies a deflection voltage to the deflector 208. Thus, the multi-beam to be shot this time is collectively deflected.

The accuracy of writing can be improved by not using any beam in which an SAA angle deviation has occurred.

In the above embodiment, when a beam in which an SAA angle deviation has occurred is identified, it is assumed that an SAA angle deviation has occurred in a plurality of beams in an area with a predetermined size around the identified beam, and the beams in the area may not be used.

The position within the array of a beam in which an SAA angle deviation has occurred is recorded, the electron optical column 102 is disassembled, then inspection, such as observation and analysis, is made on a corresponding area of the shaping aperture array substrate 203, thus dust or electrical charge cause can be efficiently identified. As a result, measures are quickly taken, and quality improvement of the shaping aperture array substrate is accomplished early. In addition, checking and cause identification of exposure of an insulator and adhesion of foreign materials can be efficiently performed by making inspection, such as observation and analysis, on corresponding areas of the blanking aperture array substrate 204. As a result, measures are quickly taken, and quality improvement of the blanking aperture array substrate is accomplished early.

In this manner, defect points which actually affect a beam trajectory can be securely and efficiently narrowed down from a great number of (for example, 260000 or more) microscopic openings or microelectrode structures, thus the efficiency of identification of a defect cause and measures against the defect cause is significantly improved, and quality improvement of the aperture array substrate is accelerated, thereby contributing to the improvement of the reliability of the apparatus, and extension of a maintenance period.

In the above embodiment, an example has been described, in which the position difference is plotted as a displacement from a normal position, and beams with a singular position difference are extracted. However, position difference measured values may be approximated by a polynomial of position, and all or part of low-degree polynomial terms such as 0th-degree, first-degree, second-degree, and third-degree terms of the approximate polynomial may be subtracted from the original position difference measured values to remove the terms with gradual change. Thus, local change in the position difference between beams is emphasized, and the beams in which an SAA angle deviation has occurred can be easily identified.

Differential processing or second or higher order differential processing may be performed on the position difference, and an obtained value may be used. Thus obtained value emphasizes the local change in the position difference, thus comparison of the position difference between beams is made easy. Note that normally, the difference between adjacent beams is substantially equivalent to differential, differential processing also includes delta processing (difference processing).

The beams in which an SAA angle deviation has occurred may be identified by setting a decision value for the above-mentioned position difference measured values, the value obtained by subtracting low-degree polynomial terms, or the value obtained by performing differential processing, and selecting the beams (beam area) having an absolute value greater than or equal to the decision value. Note that calculation processing emphasizing the local change in the position difference is not limited to low-degree polynomial term subtraction and differential processings.

In the above embodiment, an example has been described, in which beams with a singular position difference are extracted. However, the quotient of the position difference divided by the height difference Δz (=z₂−z₁) may be used. The difference in height is the difference in height of the imaging plane of a multi-beam, or the difference in height of the surface (measurement plane) of the mark 20. Alternatively, the position difference may be divided by the difference Δz in height, and a value obtained by further dividing the quotient by the angular magnification of the shaping aperture array substrate 203 may be used. The value obtained in this manner has been converted to an amount corresponding to an angle change in the vicinity of the shaping aperture array substrate 203, thus the value is preferable for comparing and reviewing the degree of the angle change regardless of a measurement timing and a target apparatus.

In the above embodiment, an example has been described, in which the beam position is measured at two heights (z₁, z₂). However, the beam position may be measured at three or more heights. An amount corresponding to the quotient of the position difference divided by the difference Δz in height is obtained by calculating the rate of change in the beam position for the imaging plane height or the measurement plane height.

The beam position measured by simply changing the excitation of the objective lens or the mark height from a completely focused state may be utilized as the position difference. This is because normally, the distortion caused by angle change in the vicinity of the shaping aperture array substrate 203 is relatively small on the completely focused imaging plane, thus the beam position measured by changing the excitation of the objective lens or the mark height from a completely focused state is a value close to the difference from the beam position measured with the excitation of the objective lens or the mark height in a completely focused state. This method has slightly less accuracy, but is simple as an advantage.

In the above embodiment, the height is set first, and the beam position is measured while maintaining the height; however, the beam to be measured for position may be set first, and the height may be changed while maintaining the beam, and the beam position may be measured at different heights.

Instead of the beam position, distortion of the entire beam shape of a multi-beam may be measured, and the beams in which an SAA angle deviation has occurred may be identified from the change in the distortion.

In the above embodiment, the position of each individual beam is measured by scanning the mark 20 with a multi-beam, and measuring reflected electrons; however, the position of each individual beam may be determined by writing a test pattern on a substrate, and measuring the position of the written pattern with a measuring instrument.

Each step in the above-described multi-beam evaluation method is executed by the control computing machine 110 controlling the control circuit 120, the detection circuit 122 and the stage position detector 124 to cause each component of the writer W to operate. The control computing machine 110 may be comprised of hardware such as an electric circuit or comprised of software. When the control computing machine 110 is comprised of software, a program to implement at least part of the function of the control computing machine 110 may be stored in a non-transitory recording medium, and read into a computer including an electric circuit (a CPU), thereby causing the computer to execute the program.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A multi charged particle beam evaluation method for evaluating trajectories of a plurality of individual beams in a multi charged particle beam which has passed through a plurality of openings provided in an aperture array substrate, the multi charged particle beam evaluation method comprising:
measuring positions of the plurality of individual beams at each of a plurality of heights, in an optical axis direction, of an imaging plane of the multi charged particle beam, or a measurement plane on which a mark for beam position measurement is formed, the plurality of heights being different from each other; and
extracting a singular beam in which a beam trajectory has changed among the plurality of individual beams based on a position difference, the position difference being a difference between beam positions of the plurality of individual beams measured at each of the plurality of heights.

2. The method according to claim 1,
wherein the height in the optical axis direction refers to the height of the imaging plane in the optical axis direction, and the imaging plane is set at each of the plurality of heights by changing an amount of excitation of a lens disposed between the aperture array substrate and the mark in the optical axis direction with the measurement plane fixed.

3. The method according to claim 1,
wherein the height in the optical axis direction refers to the height of the measurement plane in the optical axis direction, and the measurement plane is moved in the optical axis direction, and set at each of the plurality of heights with the imaging plane fixed.

4. The method according to claim 1,
wherein the position difference is approximated by a polynomial, and the singular beam is extracted based on a value obtained by subtracting predetermined low-degree terms of the polynomial from a measured value of the position difference.

5. The method according to claim 1,
wherein the singular beam is extracted based on a value obtained by performing differential processing or second or higher order differential processing on the position difference.

6. The method according to claim 1,
wherein the singular beam is extracted based on a value obtained by dividing the position difference by a corresponding height difference.

7. The method according to claim 1,
wherein the plurality of heights different from each other are a first height and a second height, and
the position difference is the difference between the beam position measured at the first height and the beam position measured at the second height.

8. A computer-readable recording medium storing a multi charged particle beam evaluation program for evaluating trajectories of a plurality of individual beams in a multi charged particle beam which has passed through a plurality of openings provided in an aperture array substrate, the program causing a computer to execute the steps of:
measuring positions of the plurality of individual beams at each of a plurality of heights, in an optical axis direction, of an imaging plane of the multi charged particle beam, or a measurement plane on which a mark for beam position measurement is formed, the plurality of heights being different from each other; and
extracting a singular beam in which a beam trajectory has changed among the plurality of individual beams based on a position difference, the position difference being a difference between beam positions of the plurality of individual beams measured at each of the plurality of heights.

9. A multi charged particle beam writing method comprising
writing a pattern on a substrate using beams other than the singular beam extracted by the evaluation method according to claim 1, the beams being among a multi charged particle beam which has passed through a plurality of openings provided in the aperture array substrate according to claim 1.

10. The method according to claim 9,
wherein a pattern is written on a substrate using beams other than beams in an area with a predetermined size around the singular beam.

11. An inspection method for an aperture array substrate for a multi charged particle beam irradiation apparatus, the inspection method comprising
inspecting the aperture array substrate according to claim 1 using position information on the singular beam extracted by the evaluation method according to claim 1.
